(19) United States
(12) Patent Application Publication
(10) Pub. No.: US 2026/0068273 A1
(43) Pub. Date: Mar. 5, 2026

(54) TRANSISTOR STRUCTURE AND MANUFACTURING METHOD THEREOF

(71) Applicant: Powerchip Semiconductor Manufacturing Corporation, Hsinchu (TW)

(72) Inventor: Meng-Han Lin, Hsinchu City (TW)

(73) Assignee: Powerchip Semiconductor Manufacturing Corporation, Hsinchu (TW)

(21) Appl. No.: 18/893,877

(22) Filed: Sep. 23, 2024

(30) Foreign Application Priority Data
Sep. 3, 2024 (TW) 113133308

(51) Int. Cl. H01L 29/423; H01L 21/762; H01L 29/40

(52) U.S. Cl. CPC H10D 64/514; H10D 64/01; H10D 64/517

(57) ABSTRACT

A transistor structure and a manufacturing method thereof are provided. The transistor structure includes a gate, doped regions and a gate dielectric structure. The gate is disposed on a substrate and includes a first portion and a second portion, wherein the second portion surrounds the first portion, and a material of the first portion is different from a material of the second portion. The doped regions are disposed in the substrate on both sides of the gate. The gate dielectric structure is disposed between the gate and the substrate.

### CROSS-REFERENCE TO RELATED APPLICATION

This application claims the priority benefit of Taiwan application serial no. 113133308, filed on Sep. 3, 2024. The entirety of the above-mentioned patent application is hereby incorporated by reference herein and made a part of this specification.

### BACKGROUND

### Technical Field

The present invention relates to a semiconductor structure, and in particular to a transistor structure.

### Description of Related Art

In the integrated circuit, the transistor device is one of the main devices. The transistor device includes a gate and source and drain regions in the substrate located on both sides of the gate. In some transistor devices, the gate may be a metal gate. The metal gate may be formed by a replacement gate process. In the replacement gate process, a polysilicon layer is removed, and a metal layer is filled in a recess formed by removing the polysilicon layer. Afterwards, a chemical mechanical polishing (CMP) process is performed to remove the metal layer outside the recess to form the metal gate in the recess.

However, when the metal gate has a large size, after the CMP process, the top surface of the metal layer in the recess may produce dishing, and thus affecting the performance of the formed transistor. In addition, in order to avoid the occurrence of dishing, a plurality of transistors with smaller-sized metal gate is formed. As a result, the size of the chip is increased, which is not conducive to the development of the micro apparatus.

### SUMMARY

The present invention provides a transistor structure and a manufacturing method thereof, wherein the gate includes a metal portion and a polysilicon portion located in the metal portion.

The transistor structure of the present invention includes a gate, doped regions and a gate dielectric structure. The gate is disposed on a substrate and includes a first portion and a second portion, wherein the second portion surrounds the first portion, and a material of the first portion is different from a material of the second portion. The doped regions are disposed in the substrate on both sides of the gate. The gate dielectric structure is disposed between the gate and the substrate.

In an embodiment of the transistor structure of the present invention, the material of the first portion includes polysilicon, and the material of the second portion includes metal.

In an embodiment of the transistor structure of the present invention, the gate dielectric structure includes a high dielectric constant layer.

In an embodiment of the transistor structure of the present invention, the gate dielectric structure further includes an interface layer disposed between the high dielectric constant layer and the substrate.

In an embodiment of the transistor structure of the present invention, the transistor structure further includes a capping layer disposed between the gate dielectric structure and the gate.

In an embodiment of the transistor structure of the present invention, a top surface of the first portion is coplanar with a top surface of the second portion.

In an embodiment of the transistor structure of the present invention, the first portion is in contact with the second portion.

In an embodiment of the transistor structure of the present invention, the first portion includes a plurality of pattern portions.

In an embodiment of the transistor structure of the present invention, the plurality of pattern portions are arranged on the substrate in an array.

The manufacturing method of the transistor structure of the present invention includes the following steps. A gate is formed on a substrate, wherein the gate includes a first portion and a second portion, the second portion surrounds the first portion, and a material of the first portion is different from a material of the second portion. A gate dielectric structure is formed between the gate and the substrate. Doped regions are formed in the substrate on both sides of the gate.

In an embodiment of the manufacturing method of the transistor structure of the present invention, the material of the first portion includes polysilicon, and the material of the second portion includes metal.

In an embodiment of the manufacturing method of the transistor structure of the present invention, the gate dielectric structure includes a high dielectric constant layer.

In an embodiment of the manufacturing method of the transistor structure of the present invention, the gate dielectric structure further includes an interface layer formed between the high dielectric constant layer and the substrate.

In an embodiment of the manufacturing method of the transistor structure of the present invention, a forming method of the gate and the gate dielectric structure includes the following steps. A gate dielectric material layer is formed on the substrate. A first gate material layer is formed on the gate dielectric material layer. The gate dielectric material layer and the first gate material layer are patterned to form the gate dielectric structure and an initial gate. A part of the initial gate is removed to form the first portion on the gate dielectric structure. The second portion is formed on the gate dielectric structure to form the gate.

In an embodiment of the manufacturing method of the transistor structure of the present invention, a forming method of the second portion includes the following steps. A second gate material layer is formed on the gate dielectric structure to cover the first portion. A part of the second gate material layer is removed until a top surface of the first portion is exposed.

In an embodiment of the manufacturing method of the transistor structure of the present invention, the doped regions are formed after patterning the gate dielectric material layer and the first gate material layer.

In an embodiment of the manufacturing method of the transistor structure of the present invention, a top surface of the first portion is coplanar with a top surface of the second portion.

In an embodiment of the manufacturing method of the transistor structure of the present invention, the first portion is in contact with the second portion.

In an embodiment of the manufacturing method of the transistor structure of the present invention, the first portion includes a plurality of pattern portions.

In an embodiment of the manufacturing method of the transistor structure of the present invention, the plurality of pattern portions are arranged on the substrate in an array.

Based on the above, in the transistor structure of the present invention, the gate includes the metal portion and the polysilicon portion located in the metal portion. Therefore, during replacing the gate, dishing at the top surface of the gate due to the CMP process may be effectively avoided.

### BRIEF DESCRIPTION OF THE DRAWINGS

FIGS. 1A to 1E are schematic cross-sectional views of the manufacturing process of the transistor structure of the embodiment of the present invention.

FIG. 2 is a top view of the gate of the transistor structure of the embodiment of the present invention.

FIG. 3 is a top view of the gate of the transistor structure of another embodiment of the present invention.

### DESCRIPTION OF THE EMBODIMENTS

The embodiments are listed below and described in detail with the accompanying drawings, but the provided embodiments are not intended to limit the scope of the present invention. In addition, the drawings are for illustration purposes only and are not drawn to original scale. In order to facilitate understanding, the same devices will be described with the same symbols in the following descriptions.

In the text, the terms mentioned in the text, such as “comprising”, “including”, “containing”and “having”are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention. Therefore, it should be understood that “on” may be used interchangeably with “under”. When a device such as a layer or a film is placed “on” another device, the device may be placed directly on the other device, or an intermediate device may be present. On the other hand, when a device is placed “directly on” another device, there is no intermediate device between the two.

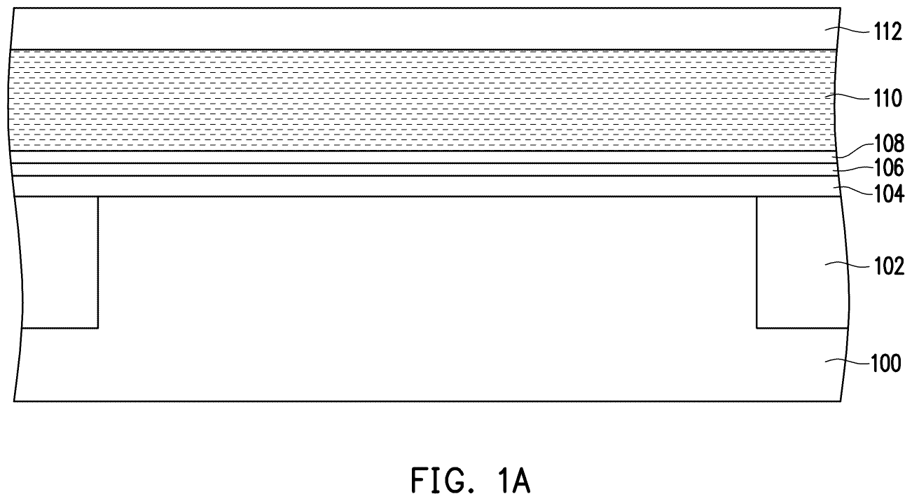

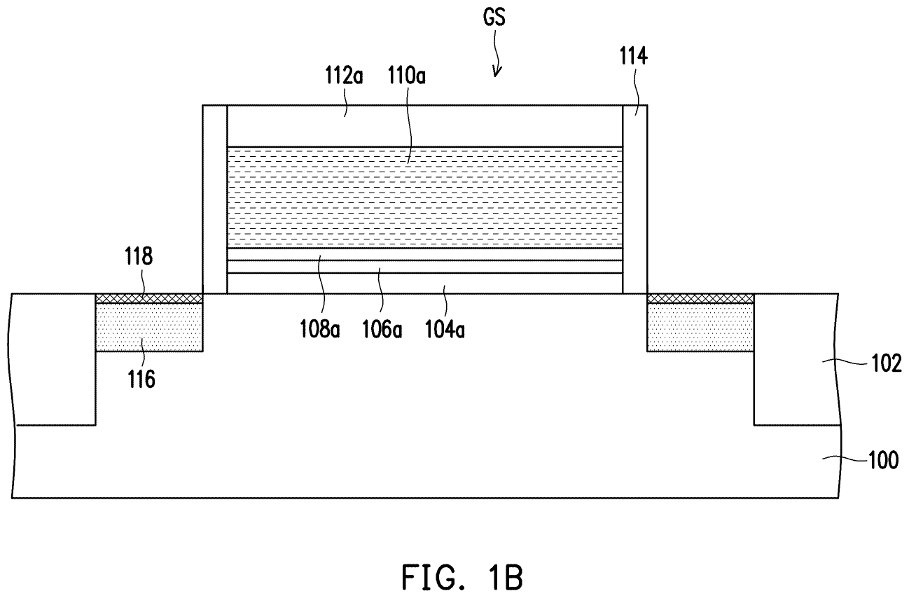

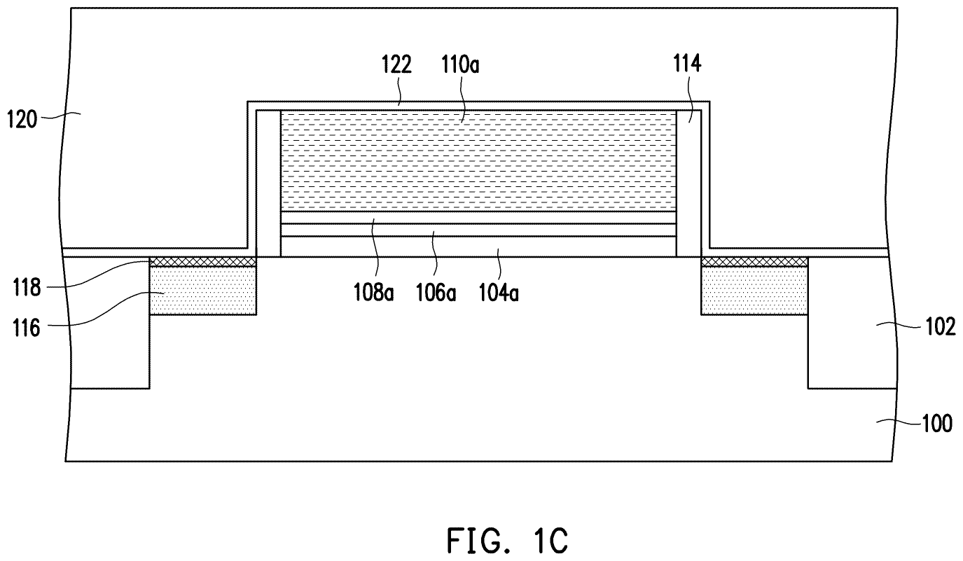

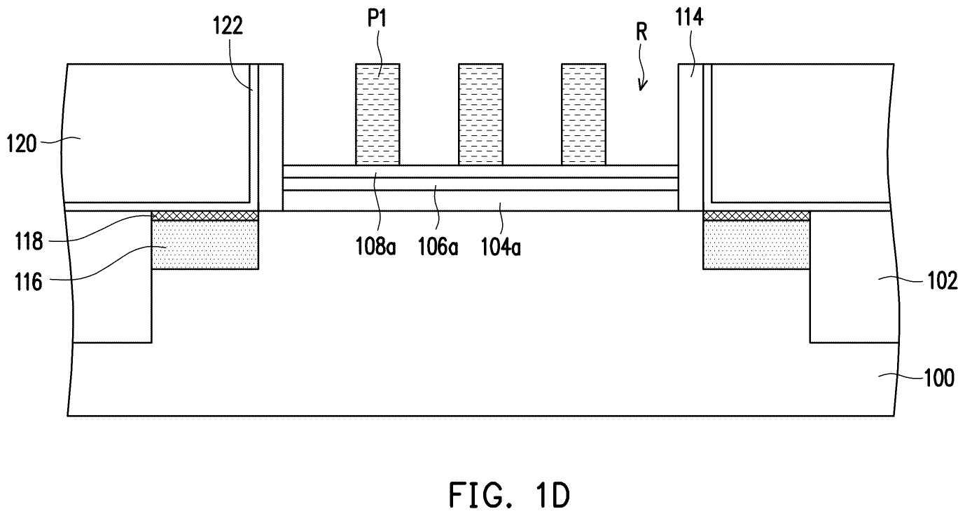

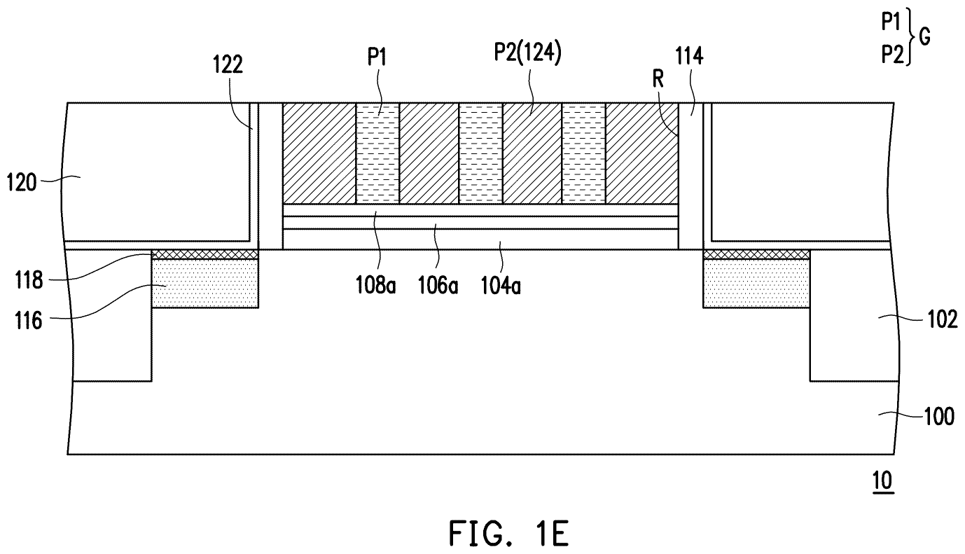

FIGS. 1A to 1E are schematic cross-sectional views of the manufacturing process of the transistor structure of the embodiment of the present invention.

Referring to FIG. 1A, a substrate 100 is provided. In the present embodiment, the substrate 100 is a silicon substrate, but the present invention is not limited thereto. Next, an isolation structure 102 is formed in the substrate 100 to define an active area. The isolation structure 102 may be a shallow trench isolation (STI) structure. The material of the isolation structure 102 may be silicon oxide. In addition, in some embodiments, after the isolation structure 102 is formed, an ion implantation process may be performed on the substrate 100 in the active area to form a well region in the substrate 100.

Then, an interface material layer 104, a gate dielectric material layer 106, a capping material layer 108, a first gate material layer 110 and a hard mask material layer 112 are formed on the substrate 100. The material of the interface material layer 104 may be silicon oxide. The material of the gate dielectric material layer 106 may be high dielectric constant (high-k) material. The high-k material usually refers to a dielectric material with a dielectric constant greater than 4 in the present technical field. The high-k material is, for example, Al₂O₃, Ta₂O₃, TiO₂, Y₂O₃, ZrO₂, HfO₂, La₂O₃, etc., but the present invention is not limited thereto. The material of the capping material layer 108 may be titanium nitride. The material of the first gate material layer 110 may be polysilicon. The material of the hard mask layer 112 may be silicon nitride.

Referring to FIG. 1B, a patterning process is performed on the interface material layer 104, the gate dielectric material layer 106, the capping material layer 108, the first gate material layer 110 and the hard mask material layer 112 to form an initial gate structure GS consisting of an interface layer (IL) 104a, a gate dielectric layer 106a, a capping layer 108a, an initial gate 110a and a hard mask layer 112a is formed. In the present embodiment, the interface layer 104a and the gate dielectric layer 106a constitute a gate dielectric structure located between gate and substrate 100, and the initial gate 110a is a polysilicon gate.

After the initial gate structure GS is formed, a spacer 114 is formed on the sidewall s of the initial gate structure GS. The material of the spacer 114 may be silicon nitride. A forming method of the spacer 114 may include the following steps. A spacer material layer is conformally formed on substrate 100. Then, an anisotropic etching process is performed on the spacer material layer until the surface of substrate 100 and the top surface of the hard mask layer 112a are exposed.

After the spacer 114 is formed, an ion implantation process is performed using the spacer 114 and the initial gate structure GS as a mask to form doped regions 116 in the substrate 100 on both sides of the initial gate structure GS. The doped regions 116 may be used as the source and drain of the transistor structure of the present embodiment. Next, a metal silicide layer 118 may be formed on the surfaces of the doped regions 116. The metal silicide layer 118 is formed by, for example, performing a self-aligned silicide (salicide) process. In the present embodiment, since the hard mask layer 112a covers the initial gate 110a, the metal silicide layer 118 may not be formed on the top surface of the initial gate 110a.

Referring to FIG. 1C, the hard mask layer 112a and a part of the spacer 114 are removed to expose the top surface of the initial gate 110a. A method for removing the hard mask layer 112a and the part of the spacer 114 is, for example, performing an etching-back process. After that, a dielectric layer 120 is formed on the substrate 100. The dielectric layer 120 covers the initial gate 110a. The dielectric layer 120 is used as an inter-layer dielectric (ILD) layer. The material of the dielectric layer 120 may be silicon oxide. In addition, before forming the dielectric layer 120, a contact etch stop layer (CESL) 122 may be conformally formed on the substrate 100. The material of the contact etch stop layer 122 may be silicon nitride.

Referring to FIG. 1D, a part of the dielectric layer 120 and a part of the contact etch stop layer 122 are removed to expose the top surface of the initial gate 110a. A method of removing a part of the dielectric layer 120 and a part of the contact etch stop layer 122 is, for example, performing a CMP process.

Then, a part of the initial gate 110a is removed, so that the remaining part of the initial gate 110a forms a first portion P1 of the gate of the transistor structure of the present embodiment on the capping layer 108a, and a recess R is formed. In detail, in the present embodiment, after removing a part of the initial gate 110a, the initial gate 110a remaining on the capping layer 108a forms a plurality of pattern portions separated from each other, and the pattern portions may be used as a portion (first portion P1) of the gate of the transistor structure of the present embodiment.

In addition, in the present embodiment, the pattern portions (first portion P1) are arranged on the capping layer 108a in an array, but the present invention is not limited thereto. In other embodiments, the pattern portions may be arranged on capping layer 108a in any form. Alternatively, in an embodiment, after removing a part of the initial gate 110a, one pattern portion may be remained as the first portion P1 of the gate of the transistor structure of the present embodiment. In addition, in the present embodiment, depending on the actual situation, the first portion P1 may have the required number, profile and size, and the invention does not limit this.

Referring to FIG. 1E, a second gate material layer 124 is formed in the recess R. The material of the second gate material layer 124 may be metal. The second gate material layer 124 is filled with the recess R to surround the first portion P1. The second gate material layer 124 is used as a second portion P2 of the gate of the transistor structure of the present embodiment. The forming method of the second gate material layer 124 may include the following steps. A gate material layer is formed on the substrate 100 to cover the dielectric layer 120 and the first portion P1, and fills the recess R. Then, a CMP process is performed to remove the gate material layer outside the recess R until the top surface of the first portion P1 is exposed. Therefore, in recess R, the second portion P2 surrounds first portion P1, the first portion P1 is in contact with the second portion P2, and the top surface of the first portion P1 is coplanar with the top surface of the second portion P2. In this way, the transistor structure 10 of the present embodiment is formed, in which the first portion P1 and the second portion P2 form the gate G of the transistor structure 10.

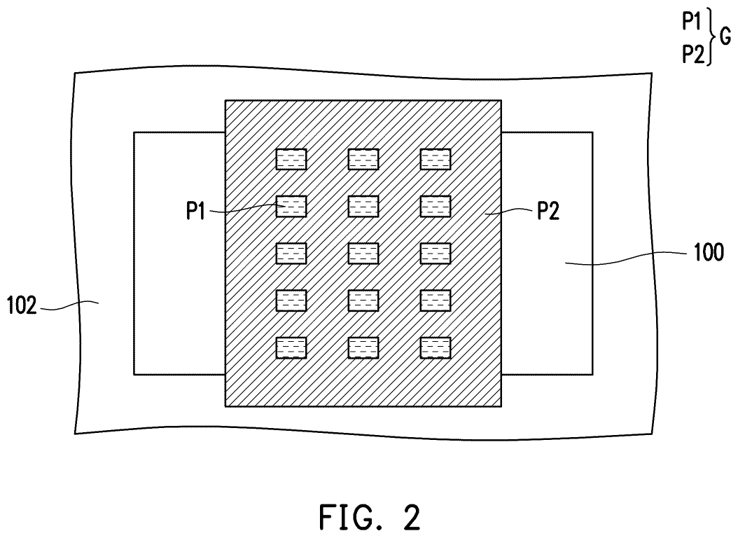

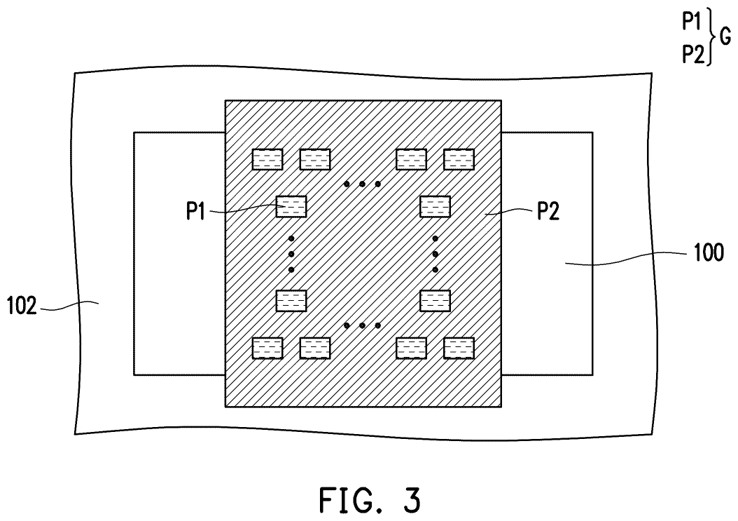

FIG. 2 is a top view of the gate G of the transistor structure 10. In FIG. 2, in order to make the figure clear and facilitate explanation, only the gate G, the substrate 100 and the isolation structure 102 are shown. As shown in FIG. 2, in the present embodiment, the gate G includes a plurality of first portions P1 and the second portions P2 surrounding the first portions P1. In addition, from the top view above the substrate 100, the first portions P1 are arranged in a 5×3 array, but the present invention is not limited thereto. In other embodiments, as shown in FIG. 3, the first portions P1 may be arranged in other types of arrays. In addition, from the top view above the substrate 100, the first portion P1 has a rectangular profile, but the present invention is not limited thereto. In other embodiments, the first portion P1 may have other shapes of profiles, such as circle shape, oval shape, square shape, etc.

In the present embodiment, the gate G is constituted by the first portion P1 with polysilicon as the material and the second portion P2 with metal as the material, so the gate G is a hybrid gate. In addition, during the CMP process for forming the second portion P2, since the first portion P1 has been formed in the recess R, the dishing at the top surface of the formed gate G may be effectively avoided.

In addition, in the present embodiment, since the gate G formed by the first portion P1 and the second portion P2 of different materials fills the recess R, the excessive reduction of the threshold voltage (Vt) of the transistor structure 10 may be effectively avoided. In the present embodiment, from the top view above the substrate 100, the area of the first portion P1 may be between 10% and 50% of the area of the gate G located directly above the gate dielectric layer 106a. In this way, in addition to avoiding the dishing at the surface of the gate G after the CMP process, the excessive reduction of the threshold voltage of the transistor structure 10 may be effectively avoided due to an excessively high proportion of the first portion P1.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A transistor structure, comprising:
a gate, disposed on a substrate and comprising a first portion and a second portion, wherein the second portion surrounds the first portion, and a material of the first portion is different from a material of the second portion;
doped regions, disposed in the substrate on both sides of the gate; and
a gate dielectric structure, disposed between the gate and the substrate.

2. The transistor structure of claim 1, wherein the material of the first portion comprises polysilicon, and the material of the second portion comprises metal.

3. The transistor structure of claim 2, wherein the gate dielectric structure comprises a high dielectric constant layer.

4. The transistor structure of claim 3, wherein the gate dielectric structure further comprises an interface layer disposed between the high dielectric constant layer and the substrate.

5. The transistor structure of claim 1, further comprising a capping layer disposed between the gate dielectric structure and the gate.

6. The transistor structure of claim 1, wherein a top surface of the first portion is coplanar with a top surface of the second portion.

7. The transistor structure of claim 1, wherein the first portion is in contact with the second portion.

8. The transistor structure of claim 1, wherein the first portion comprises a plurality of pattern portions.

9. The transistor structure of claim 8, wherein the plurality of pattern portions are arranged on the substrate in an array.

10. A manufacturing method of a transistor structure, comprising:
forming a gate on a substrate, wherein the gate comprises a first portion and a second portion, the second portion surrounds the first portion, and a material of the first portion is different from a material of the second portion;
forming a gate dielectric structure between the gate and the substrate; and
forming doped regions in the substrate on both sides of the gate.

11. The manufacturing method of claim 10, wherein the material of the first portion comprises polysilicon, and the material of the second portion comprises metal.

12. The manufacturing method of claim 10, wherein the gate dielectric structure comprises a high dielectric constant layer.

13. The manufacturing method of claim 12, wherein the gate dielectric structure further comprises an interface layer formed between the high dielectric constant layer and the substrate.

14. The manufacturing method of claim 10, wherein a forming method of the gate and the gate dielectric structure comprises:
forming a gate dielectric material layer on the substrate;
forming a first gate material layer on the gate dielectric material layer;
patterning the gate dielectric material layer and the first gate material layer to form the gate dielectric structure and an initial gate;
removing a part of the initial gate to form the first portion on the gate dielectric structure; and
forming the second portion on the gate dielectric structure to form the gate.

15. The manufacturing method of claim 14, wherein a forming method of the second portion comprises:
forming a second gate material layer on the gate dielectric structure to cover the first portion; and
removing a part of the second gate material layer until a top surface of the first portion is exposed.

16. The manufacturing method of claim 14, wherein the doped regions are formed after patterning the gate dielectric material layer and the first gate material layer.

17. The manufacturing method of claim 10, wherein a top surface of the first portion is coplanar with a top surface of the second portion.

18. The manufacturing method of claim 10, wherein the first portion is in contact with the second portion.

19. The manufacturing method of claim 10, wherein the first portion comprises a plurality of pattern portions.

20. The manufacturing method of claim 19, wherein the plurality of pattern portions are arranged on the substrate in an array.
